(19) United States
(12) Patent Application Publication
(10) Pub. No.: US 2024/0096681 A1
(43) Pub. Date: Mar. 21, 2024

(54) WAFER ASSEMBLY AND METHOD FOR PRODUCING A PLURALITY OF SEMICONDUCTOR CHIPS

(71) Applicant: ams-OSRAM International GmbH, Regensburg (DE)

(72) Inventors: Teresa Baur, Regensburg (DE); Christoph Kiemp, Regensburg (DE)

(21) Appl. No.: 18/263,240

(22) PCT Filed: Jan. 12, 2022
(86) PCT No.: PCT/EP2022/050523

§ 371 Date: Jul. 27, 2023

(30) Foreign Application Priority Data
Feb. 1, 2021 (DE) 102021200897.6

(51) Int. Cl. H01L 21/683; G01R 31/26; H01L 21/66; H01L 21/768

(52) U.S. Cl. CPC H01L 21/6835; G01R 31/2644; H01L 21/76898; H01L 22/30

(57) ABSTRACT

Embodiments provide a wafer assembly including a plurality of semiconductor chips, wherein each semiconductor chip has a first main face and a second main face opposite the first main face, and wherein a first electrical contact is disposed on the second main face, a plurality of electrically conducting posts, wherein each first electrical contact is in direct contact with an electrically conducting post, and an electrically insulating sacrificial layer having passages in which the electrically conducting posts are disposed.

### CROSS-REFERENCE TO RELATED APPLICATIONS

This patent application is a national phase filing under section 371 of PCT/EP2022/050523, filed Jan. 12, 2022, which claims the priority of German patent application 10 2021 200 897.6, filed Feb. 1, 2021, each of which is incorporated herein by reference in its entirety.

### TECHNICAL FIELD

A wafer assembly and a method for producing a plurality of semiconductor chips are specified.

### SUMMARY

Embodiments provide a wafer assembly having a plurality of semiconductor chips, with which the semiconductor chip can be tested particularly simply. Further embodiments provide a method for producing a plurality of semiconductor chips, during which the semiconductor chips can be tested particularly simply.

According to one embodiment, the wafer assembly comprises a plurality of semiconductor chips. Each semiconductor chip has a first main face and a second main face which is opposite the first main face. Disposed on the second main face is a first electrical contact which is intended for electrically contacting the electrical semiconductor chip.

The semiconductor chips of the wafer assembly may be alike or else different from one another in design. Features and embodiments which are presently described, only for simplicity, in connection with one semiconductor chip may be embodied in some of or in all the semiconductor chips of the wafer assembly.

According to a further embodiment of the wafer assembly, the semiconductor chip on the first main face has a second electrical contact which is likewise intended for electrically contacting the semiconductor chip (vertical semiconductor chip).

According to a further embodiment of the wafer assembly, the second electrical contact and the first electrical contact are disposed on the second main face. A semiconductor chip with an arrangement of this kind of the first electrical contact and of the second electrical contact is also called a flip-chip.

According to one embodiment of the wafer assembly, the semiconductor chip is radiation-emitting. For this purpose, the semiconductor chip generally has an epitaxial semiconductor layer sequence which comprises an active zone. The active zone is configured to generate electromagnetic radiation in operation.

According to a further embodiment, the wafer assembly comprises a plurality of electrically conducting posts, with each first electrically conducting contact being in direct contact with an electrically conducting post. In this case, for example, each first electrical contact is assigned exactly one electrically conducting post. The electrically conducting post and the first electrical contact of the semiconductor chip are in direct contact with one another in this case, so that the electrically conducting post and the first electrical contact are connected to one another in an electrically conducting manner. Alternatively, it is also possible for each first electrical contact to be assigned more than one electrically conducting post.

Where the semiconductor chip is a flip-chip, each second electrically conducting contact is preferably also in direct contact with an electrically conducting post. In this case, for example, each second electrical contact is assigned exactly one electrically conducting post. The electrically conducting post and the second electrical contact of the flip-chip in this case are in direct contact with one another, so that the electrically conducting post and the second electrical contact are connected to one another in an electrically conducting manner. Alternatively, it is also possible for each second electrical contact to be assigned more than one electrically conducting post.

According to a further embodiment, the wafer assembly additionally comprises an electrically insulating sacrificial layer having passages in which the electrically conducting posts are disposed. The passages penetrate the electrically insulating sacrificial layer, with particular preference completely. The electrically insulating sacrificial layer insulates the electrically conducting posts from one another. The electrically conducting posts are preferably disposed completely within the passages. Each electrically conducting post preferably completely fills a passage.

According to one particularly preferred embodiment, the wafer assembly comprises:
a plurality of semiconductor chips, where each semiconductor chip has a first main face and a second main face which is opposite the first main face, and where a first electrical contact is disposed on the second main face,
a plurality of electrically conducting posts, where each first electrical contact is in direct contact with an electrically conducting post, and
an electrically insulating sacrificial layer having passages, in which the electrically conducting posts are disposed.

According to a further embodiment of the wafer assembly, the first electrical contact is contactable in an electrically conducting manner by way of the electrically conducting post. In other words, the electrically conducting post produces an electrically conducting connection between the first electrical contact of the semiconductor chip and an external electrical terminal point.

Where the semiconductor chip is a flip chip, the second electrical contact is also contactable in an electrically conducting manner by way of the electrically conducting post. In other words, the electrically conducting post produces an electrically conducting connection between the second electrical contact of the flip chip and an external electrical terminal point.

The electrically insulating sacrificial layer comprises, for example, a dielectric, such as a nitride or an oxide, or consists of one of these materials. For example, the sacrificial layer comprises silicon nitride or silicon dioxide or consists of one of these materials.

According to a further embodiment of the wafer assembly, the electrically insulating sacrificial layer extends over the full area along a back-side main face of the wafer assembly. With particular preference, the electrically insulating sacrificial layer embeds the first electrical contacts. Where the semiconductor chip is a flip-chip, the electrically insulating sacrificial layer preferably embeds the first electrical contacts and the second electrical contacts.

A thickness of the electrically insulating sacrificial layer is preferably between, inclusively, 100 nanometers and, inclusively, 500 nanometers.

According to a further embodiment of the wafer assembly, the semiconductor chip is free of a material which the electrically insulating sacrificial layer comprises or of which the electrically insulating sacrificial layer consists. Hence the electrically insulating sacrificial layer may be removed at a later point in time without damage to the semiconductor chip.

According to a further embodiment of the wafer assembly, an electrically conducting material of the electrically conducting post extends as an electrically conducting layer over the full area along the back-side main face of the wafer assembly. The electrically conducting layer here is preferably in direct contact with the electrically insulating sacrificial layer. The electrically insulating sacrificial layer is preferably disposed between the electrically conducting layer and the semiconductor chip.

A thickness of the electrically conducting layer is, for example, between 100 nanometers and, inclusively, 500 nanometers.

According to a further embodiment of the wafer assembly, a region of the electrically conducting post and a region of the first electrical contact which directly border one another comprise materials different from one another or are formed of materials different from one another. Hence the electrically conducting post and the first electrical contact can be parted spatially from one another at a later point in time in a particularly simple manner.

Where the semiconductor chip is a flip-chip, a region of the electrically conducting post and a region of the second electrical contact which directly border one another also comprise materials different from one another or are formed of materials different from one another. Hence the electrically conducting post and the second electrical contact can also be parted spatially from one another at a later point in time in a particularly simple manner.

According to a further embodiment of the wafer assembly, the electrically conducting material of the electrically conducting post is at least one material from the following group: transparent conductive oxide (TCO), metal, semimetal. In other words, the electrically conducting post comprises a TCO or metal or a semimetal or is formed of one of these materials.

Transparent conductive oxides are generally metal oxides, such as zinc oxide, tin oxide, cadmium oxide, titanium oxide, indium oxide or indium tin oxide (ITO), for example. As well as binary metal-oxygen compounds, such as ZnO, SnO₂ or In₂O₃, for example, ternary metal-oxygen compounds as well, such as Zr₂SnO₄, ZnSnO₃, MgIn₂O₄, GaInO₃, Zn₂In₂O₅ or In₄Sn₃O₁₂, for example, or mixtures of different transparent conductive oxides, also belong to the group of the TCOs. Additionally, the TCOs do not automatically correspond to a stochiometric composition and may additionally also have p- and also n-doping.

An especially suitable material for the electrically conducting post is one of the following TCOs: ITO (indium tin oxide), ZnO (zinc oxide), IZO (indium zinc oxide), FTO (fluorine-doped tin oxide, SnO₂:F), ATO (antimony-doped tin oxide, SnO₂:Sb).

Additionally suitable as material for the electrically conducting post is, in particular, at least one of the following (semi)metals and their alloys: Au, Al, Cr, Ti, Pt, Cu, WTi, Sn, Ag, Ni, Zn, Rh, Ru, W, In, Ge, AuGe, AlSiCu, NiSn, AuSn, AuZn, AuIn, AuInSn.

According to a further embodiment of the wafer assembly, the first electrical contact and/or the second electrical contact have/has a first contact layer which is directly adjacent to the electrically conducting post. The first contact layer may comprise, for example, a (semi)metal or an alloy of a (semi)metal, or a TCO, or may be formed of a (semi)metal or an alloy of a (semi)metal, or a TCO. A suitable TCO is, for example, one of the following materials: ITO, ZnO, IZO, FTO, ATO, whereas a suitable (semi)metal or alloy of a (semi)metal is at least one of the following materials: Au, Al, Cr, Ti, Pt, Cu, WTi, Sn, Ag, Ni, Zn, Rh, Ru, W, In, Ge, AuGe, AlSiCu, NiSn, AuSn, AuZn, AuIn, AuInSn.

A thickness of the first contact layer is, for example, between, inclusively, 100 nanometers and, inclusively, 500 nanometers.

According to a further embodiment of the wafer assembly, the first electrical contact and/or the second electrical contact have/has a second contact layer. For example, the first electrical contact and/or the second electrical contact are/is formed by the first contact layer and the second contact layer.

According to one particularly preferred embodiment of the wafer assembly, a predetermined breakage layer forms at least one end face of the electrically conducting post. By means of the predetermined breakage layer it is possible in particular to create a region of the electrically conducting post in a material different from the material of the adjacent region of the first electrical contact and/or of the second electrical contact. The predetermined breakage layer may in particular be optimized such that later detachment of the electrically conducting post from the first electrical contact and/or the second electrical contact may be carried out in a particularly simple manner. For this purpose, for example, material and/or thickness of the predetermined breakage layer are/is selected accordingly.

A thickness of the predetermined breakage layer is, for example, between, inclusively, to nanometers and, inclusively, 50 nanometers.

The predetermined breakage layer may also either comprise a TCO or a (semi)metal or an alloy of a (semi)metal, or consist of one of these materials. For example, one of the following TCOs is a suitable material: ITO, ZnO, IZO, FTO, ATO, whereas at least one of the following materials is suitable as (semi)metal or alloy of a (semi)metal: Au, Al, Cr, Ti, Pt, Cu, WTi, Sn, Ag, Ni, Zn, Rh, Ru, W, In, Ge, AuGe, AlSiCu, NiSn, AuSn, AuZn, AuIn, AuInSn.

According to a further embodiment of the wafer assembly, the predetermined breakage layer extends over the full area along a back-side main face of the wafer assembly. For example, the predetermined breakage layer is applied in direct contact to the electrically conducting layer and to the electrically conducting post. For example, the predetermined breakage layer is disposed between the electrically insulating sacrificial layer and the electrically conducting layer.

According to a further embodiment of the wafer assembly, the predetermined breakage layer is directly adjacent to the first electrical contact and/or to the second electrical contact. With particular preference, the predetermined breakage layer comprises a material which is different from the material of the region of the first electrical contact and/or of the second electrical contact that is directly adjacent to the predetermined breakage layer. Where the first electrical contact and/or the second electrical contact have/has a first contact layer, the material of the predetermined breakage layer is different, for example, from the material of the first contact layer.

According to a further embodiment of the wafer assembly, the material of the predetermined breakage layer is different from the rest of the material of the electrically conducting post.

According to a further embodiment of the wafer assembly, an edge length of the semiconductor chip is not greater than 100 micrometers, preferably not greater than 80 micrometers, with particular preference not greater than 50 micrometers.

According to one embodiment, the wafer assembly comprises a carrier. The carrier with particular preference mechanically stabilizes the wafer assembly. The carrier is preferably connected to the electrically conducting layer in an electrically conducting manner. For example, the carrier is bonded to the electrically conducting layer. The carrier likewise preferably comprises an electrically conducting material: germanium, for example. A main face of the carrier preferably forms the back-side main face of the wafer assembly.

The wafer assembly described here is especially suitable for use in a method for producing a plurality of semiconductor chips. Features and embodiments described presently in connection with the wafer assembly may also be embodied in the context of the method, and vice versa.

According to one embodiment of the method for producing a plurality of semiconductor chips, a wafer assembly as already described is provided.

According to a further embodiment of the method, the semiconductor chips of the wafer assembly are tested, with the semiconductor chips being electrically contacted by way of a back-side main face of the wafer assembly. This is possible in particular in a simple manner by way of the electrically conducting posts, which are in direct contact with the first electrical contact and/or with the second electrical contact of the semiconductor chip.

According to one preferred embodiment, the method for producing a plurality of semiconductor chips comprises the following steps:
providing a wafer assembly comprising a plurality of semiconductor chips, where each semiconductor chip has a first main face and a second main face which is opposite the first main face, and where a first electrical contact is disposed on the second main face, and additionally comprising a plurality of electrically conducting posts, where each first electrical contact is in direct contact with an electrically conducting post, and comprising, moreover, an electrically insulating sacrificial layer having passages in which the electrically conducting posts are disposed,
testing the semiconductor chips of the wafer assembly, the semiconductor chips being electrically contacted by way of a back-side main face of the wafer assembly.

The steps of the method are preferably carried out in the order stated.

According to a further embodiment of the method, the electrically insulating sacrificial layer is removed from the wafer assembly, preferably after the testing. Following removal of the electrically insulating sacrificial layer from the wafer assembly, the semiconductor chips are preferably connected mechanically to the wafer assembly only by way of the electrically conducting posts.

According to a further embodiment of the method, the semiconductor chips are parted mechanically from the electrically conducting posts, using a pick-and-place-method, for example.

It is presently a concept to provide a wafer assembly with a plurality of semiconductor chips wherein the semiconductor chips may be electrically contacted by way of the first electrical contact and/or the second electrical contact which points to a back-side main face of the wafer assembly. The electrical contacting in this arrangement is by way of an electrically conducting post having comparatively small dimensions. With particular preference, the electrically conducting posts are embedded in an electrically insulating sacrificial layer which is removed from the wafer assembly at a later point in time, after the testing, so that the semiconductor chips are connected mechanically only by way of the electrically conducting posts. Especially when using a predetermined breakage layer, as already described above, the semiconductor chips may then be removed from the wafer assembly in a simple manner, by a pick-and-place method, for example. A method of this kind is especially suitable for semiconductor chips having low edge lengths.

### BRIEF DESCRIPTION OF THE DRAWINGS

Further advantageous embodiments and developments of the wafer assembly and of the method are evident from the exemplary embodiments described below in conjunction with the figures.

FIG. 1 shows a schematic sectional representation of a wafer assembly according to one exemplary embodiment;

FIG. 2 shows a schematic sectional representation of a detail of the wafer assembly according to the exemplary embodiment of FIG. 1;

FIG. 3A shows a schematic sectional representation of the detail of the wafer assembly as marked in FIG. 2 according to a further exemplary embodiment;

FIG. 3B shows a schematic sectional representation of the detail of the wafer assembly as marked in FIG. 2 according to the exemplary embodiment of FIG. 1;

FIG. 3C shows a schematic sectional representation of the detail of the wafer assembly as marked in FIG. 2 according to a further exemplary embodiment;

FIG. 4 shows a schematic sectional representation of a stage of a method according to one exemplary embodiment;

FIG. 5 shows a schematic sectional representation of a further stage of the method according to the exemplary embodiment of FIG. 1;

FIG. 6 shows a schematic sectional representation of a further stage of the method according to the exemplary embodiment of FIG. 1;

FIG. 7 shows a schematic sectional representation of a further stage of the method according to the exemplary embodiment of FIG. 1; and

FIG. 8 shows a schematic sectional representation of a wafer assembly according to a further exemplary embodiment.

### DETAILED DESCRIPTION OF ILLUSTRATIVE EMBODIMENTS

Elements which are the same or of the same kind or which have the same effect are provided in the figures with the same reference signs. The figures and the proportions of the elements represented in the figures to one another should not be considered as being to scale. Instead, the size of certain elements, especially layer thicknesses, may be exaggerated for more effective representation and/or for better understanding.

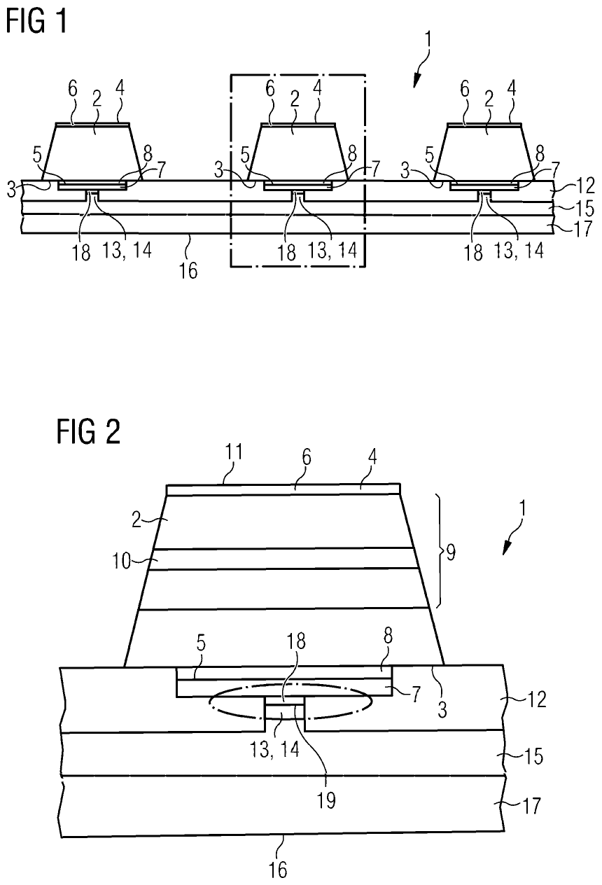

The wafer assembly 1 according to the exemplary embodiment of FIGS. 1, 2 and 3B comprises a plurality of semiconductor chips 2. Each semiconductor chip 2 has a first main face 3 and a second main face 4, the second main face 3 being opposite the first main face 4. Disposed on the second main face 4 is a first electrical contact 5, and on the first main face 3 a second electrical contact 6. The semiconductor chips as per FIGS. 1, 2 and 3B are therefore vertical semiconductor chips. By way of the first electrical contact 5 and the second electrical contact 6, the semiconductor chip 2 may be electrically contacted for operation.

Each first electrical contact 5 is presently formed of a first contact layer 7 and a second contact layer 8, the first contact layer 7 and the second contact layer 8 being directly adjacent to one another.

The semiconductor chips 2 of the wafer assembly 1 according to the exemplary embodiment of FIGS. 1, 2 and 3B are presently of the same kind. Additionally, it is also possible for the semiconductor chips 2 to differ from one another.

For example, the semiconductor chips 2 are radiation-emitting. In other words, the semiconductor chips 2 are embodied and configured to emit electromagnetic radiation in operation. For this purpose, the semiconductor chip 2 comprises an epitaxial semiconductor layer sequence 9 which comprises an active zone 10 (FIG. 2). In the operation of the semiconductor chip 2, in the active zone 10, electromagnetic radiation is generated, and is emitted from a radiation exit face 11.

Additionally, the wafer assembly 1 comprises an electrically insulating sacrificial layer 12. The electrically insulating sacrificial layer 12 is directly adjacent to the first main face 3 of the semiconductor chips 2 and embeds the first electrical contacts 5 of the semiconductor chips 2. The sacrificial layer 12, which has little electrical conductivity or is electrically insulating, comprises, for example, germanium, silicon, silicon nitride or silicon oxide, or consists of one of these materials. The silicon oxide may have different forms. For example, the silicon oxide may be a thermal oxide, a tetraethyl orthosilicate (TEOS), an SiH4 PECVD, a quartz, a spin-on-glass or a SOI (short for “silicon on insulator”).

The electrically insulating sacrificial layer 12 is envisaged and configured to be removed from the wafer assembly 1 at a later point in time, by wet-chemical or dry-chemical means, for example. Dry-chemical methods used may be an SF6 plasma, XeF2 vapor or HF vapor (VHF).

For removal of the electrically insulating sacrificial layer 12, the semiconductor chips 2 are preferably free of the material of which the electrically insulating sacrificial layer 12 is formed.

Where the semiconductor chips 2 contain regions with material of which the electrically insulating sacrificial layer 12 is formed, these regions are generally encapsulated with respect to the wet-chemical or dry-chemical removal.

The electrically insulating sacrificial layer 12 contains passages 13 in which electrically conducting posts 14 are disposed. The electrically conducting posts 14 are directly adjacent to the first electrical contacts 5 and in particular to the first contact layers 7 of the first electrical contacts 5. In this way, the electrically conducting posts 14 are connected in an electrically conducting manner to the first electrical contacts 5.

Additionally, a material of the electrically conducting posts 13 extends as an electrically conducting layer 15 over the full area along a back-side main face 16 of the wafer assembly 1. The electrically conducting layer 15 is in direct contact with the electrically insulating sacrificial layer 12. The electrically conducting posts 14 protrude from the electrically conducting layer 13 and are directly adjacent to the first contact layers 7 of the first electrical contacts 5.

Additionally, the wafer assembly 1 comprises a carrier 17 which mechanically stabilizes the wafer assembly 1. The carrier 17 is presently electrically conducting and is directly adjacent to the electrically conducting layer 15. A main face of the electrically conducting carrier 17 forms the back-side main face 16 of the wafer assembly 1. For example, the carrier 17 is connected in a mechanically stable manner, by bonding, for example, to the electrically conducting layer 15. Additionally, it is also possible for the connection between the electrically conducting layer 15 and the carrier 17 to have an easily partable embodiment. For example, the carrier is connected mechanically stably but easily partably to the rest of the wafer assembly 1 by an adhesive film (not represented).

The electrically conducting post 14 presently has a predetermined breakage layer 18. The predetermined breakage layer 18 is comprised, for example, by an end face 19 of the electrically conducting post 14.

In the case of the wafer assembly 1 according to the exemplary embodiment of FIGS. 1, 2 and 3B, the predetermined breakage layer 18 is embodied only on the end face 19 of the electrically conducting post 14, while side faces 22 of the electrically conducting post 14 are free of the predetermined breakage layer 18. A predetermined breakage layer 18 of this kind may be generated by means of lithography, for example.

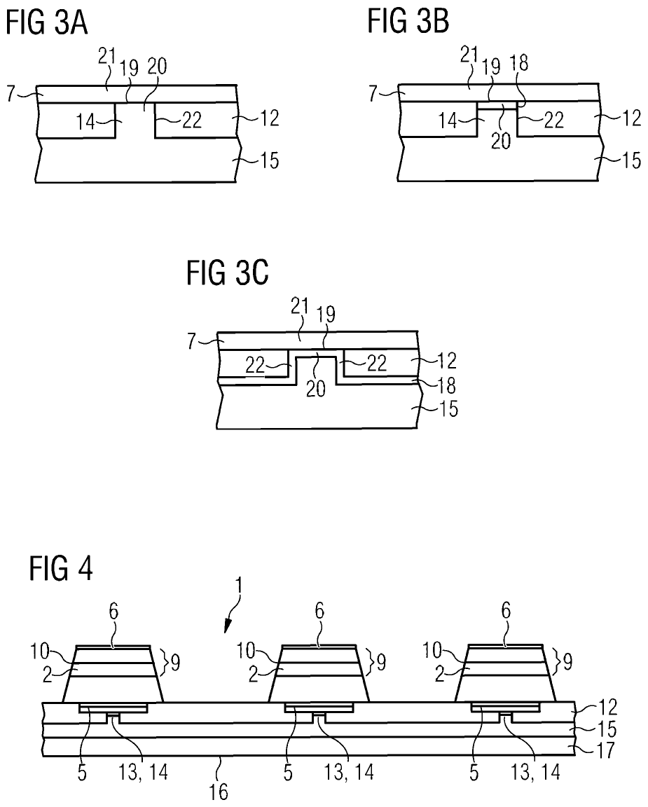

FIGS. 3A, 3B and 3C show three different exemplary embodiments of the junction between the electrically conducting post 14 and the first electrical contact 5 of the semiconductor chip 2.

In the case of the wafer assembly 1 according to the exemplary embodiment of FIG. 3A, the electrically conducting post 14 is formed continuously of a single electrically conducting material. The electrically conducting post 14 is formed, for example, of a TCO or of a (semi)metal or of an alloy of a (semi)metal. The first contact layer 7 of the first electrical contact 5 is likewise formed of an electrically conducting material, which is preferably different from the electrically conducting material of the electrically conducting post 14. In other words, a region 20 of the electrically conducting post 14 and a region 21 of the first electrical contact 5, which are directly adjacent to one another, comprise materials different from one another.

Where the electrically conducting post 14 comprises a TCO, the first contact layer 7 is formed, for example, of a (semi)metal or of an alloy of a (semi)metal. Additionally, it is also possible for the electrically conducting post 14 to be formed of a TCO and for the first contact layer 7 to be formed of a different TCO, which differs from the TCO of the electrically conducting post 14. Additionally, the electrically conducting post 14 and the first contact layer 7 may also be formed of two different (semi)metals or alloys (semi)metals. In other words, the electrically conducting post 14 comprises a (semi)metal or an alloy of a (semi)metal that is different from a (semi)metal or an alloy of a (semi)metal of the first contact layer 7.

Possible combinations of materials for the electrically conducting post 14 and for the first contact layer 7 are contained in the first four lines of table 1 below. To indicate that the TCOs and the (semi)metals are different from one another, they are each provided with a digit.

In the case of the wafer assembly 1 according to the exemplary embodiment of FIG. 3B, an end face 19 of the electrically conducting post 14 is formed by a predetermined breakage layer 18. The predetermined breakage layer 18 is directly adjacent to the first contact layer 7 of the electrical contact 5. The predetermined breakage layer 18 comprises a different material from the first contact layer 7. Additionally, the predetermined breakage layer 18 comprises a different material from the rest of the electrically conducting post 14. Suitable combinations of materials are specified in table 1 in lines 5 to 8.

Where the predetermined breakage layer 18 comprises a TCO, the first contact layer 7 and the rest of the material of the electrically conducting post 14 may likewise comprise a TCO, which, however, differs from the TCO of the predetermined breakage layer 18. Additionally, the rest of the material of the electrically conducting post 14 and/or the first contact layer 7 may also comprise a (semi)metal or consist of a (semi)metal. Lastly, it is also possible for the predetermined breakage layer 18, the rest of the material of the electrically conducting post 14, and the first contact layer 7 each to comprise a (semi)metal or be formed of a (semi)metal. In this case, at least the predetermined breakage layer 18 comprises a different (semi)metal from the first contact layer 7 and from the rest of the material of the electrically conducting post 14.

TABLE 1

| | Material of the | |
|---|---|---|
| First contact | electrically | Predetermined |
| layer 7 | conducting post 14 | breakage layer 18 |
| TCO 1 | TCO 2 | none |
| TCO | (semi)metal | none |
| (semi)metal | TCO | none |
| (semi)metal 1 | (semi)metal 2 | none |
| TCO 1 | TCO 2 | TCO 3 |
| TCO 1 | (semi)metal | TCO 2 |
| (semi)metal | TCO 1 | TCO 2 |
| TCO 1 | TCO 2 | (semi)metal |
| TCO | (semi)metal 1 | (semi)metal 2 |
| (semi)metal 1 | TCO | (semi)metal 2 |
| (semi)metal 1 | (semi)metal 2 | TCO |
| (semi)metal 1 | (semi)metal 2 | (semi)metal 3 |

In the case of the wafer assembly 1 according to the exemplary embodiment of FIG. 3C, the predetermined breakage layer 18 extends not only over the end face 19 of the electrically conducting post 14, but also over side faces 22 of the electrically conducting post 14 and over the full area along a back-side main face 16 of the wafer assembly. The predetermined breakage layer 18 here is in direct contact with the electrically conducting layer 15 and with the electrically insulating sacrificial layer 12.

In the method according to the exemplary embodiment of FIGS. 4 to 7, a wafer assembly 1 is provided in a first step. For example, the wafer assembly 1 is the wafer assembly 1 as has already been described with reference to FIGS. 1, 2 and 3B.

The wafer assembly 1 comprises a plurality of semiconductor chips 2. For example the semiconductor chips 2 are radiation-emitting semiconductor chips 2 having an epitaxial semiconductor layer sequence 9 which comprises an active zone 10 in which electromagnetic radiation is generated in operation. The semiconductor chips 2 may be of the same kind or different from one another. In particular it is possible for the semiconductor chips 2 in operation to emit electromagnetic radiation of different color.

A semiconductor chip 2 which in operation emits electromagnetic radiation from the red to infrared spectral range generally comprises an epitaxial semiconductor layer sequence 9 which is based on an arsenide compound semiconductor material. Arsenide compound semiconductor materials are compound semiconductor materials which contain arsenic, such as the materials of the system InₓAl_{y}Ga_{1-x-y}As with 0≤x≤1, 0≤y≤1 and x+y≤1.

A semiconductor chip 2 which in operation emits electromagnetic radiation from the red to green spectral range generally comprises an epitaxial semiconductor layer sequence 9 which is based on a phosphide compound semiconductor material. Phosphide compound semiconductor materials are compound semiconductor materials which contain phosphorus, such as the materials of the system InₓAl_{y}Ga_{1-x-y}P with 0≤x≤1, 0≤y≤1 and x+y≤1.

A semiconductor chip 2 which in operation emits electromagnetic radiation from the blue to ultraviolet spectral range generally comprises an epitaxial semiconductor layer sequence 9 which is based on a nitride compound semiconductor material. Nitride compound semiconductor materials are compound semiconductor materials which contain nitrogen, such as the materials of the system InₓAl_{y}Ga_{1-x-y}N with 0≤x≤1, 0≤y≤1 and x+y≤1.

Additionally, each semiconductor chip 2 has a first electrical contact 5 on a second main face 4 and has a second electrical contact 6 on a first main face 3 which is opposite the second main face 4.

In a subsequent step, which is represented schematically in FIG. 5, the semiconductor chips 2 are tested, for their functional capability, for example. The semiconductor chips 2 are presently tested one after another, i.e., serially. For testing the semiconductor chip 2, a voltage U is applied between the first electrical contact 5 of the semiconductor chip 2 and the second electrical contact 6 of the semiconductor chip 2. When a voltage U is applied to the first electrical contact 5 and to the second electrical contact 6 of the semiconductor chip 2, current flows through the epitaxial semiconductor layer sequence 9 and in particular through the active zone 10, and so electromagnetic radiation is generated.

Since the carrier 17, the electrically conducting layer 15 and the electrically conducting posts 14 are electrically conducting, it is particularly simple to apply a voltage U to the semiconductor chips 2 temporarily one after another and so to operate them for testing.

For example, the semiconductor chips 2 may be functionally tested in this way. Additionally, it is possible during the testing to determine a color locus of the electromagnetic radiation of the semiconductor chips 2 and to sort the semiconductor chips 2 according to the color loci of the electromagnetic radiation.

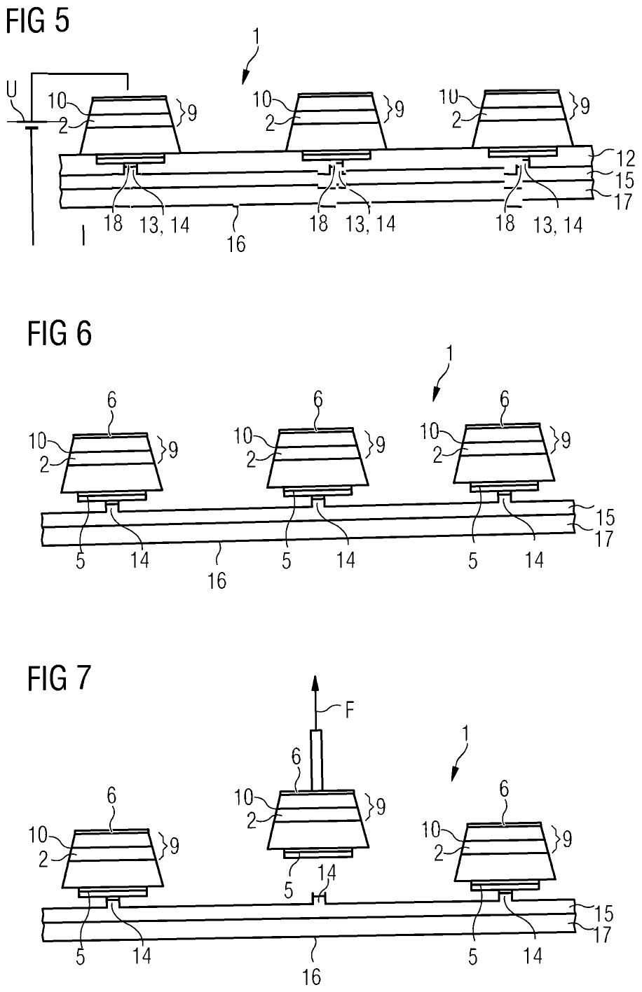

In a subsequent step, the electrically insulating sacrificial layer 12 is removed from the wafer assembly 1 (FIG. 6). For example, the electrically insulating sacrificial layer 12 is removed wet-chemically. Especially for the wet-chemical removal of the electrically insulating sacrificial layer 12, it is advantageous if the material of the electrically insulating sacrificial layer 12 is not contained in the rest of the wafer assembly 1 and in particular not in the semiconductor chips 2. In this case, the wafer assembly 1 may be introduced in its entirety into the medium for the wet-chemical removal, without damage to the semiconductor chips 2.

In a subsequent step, the semiconductor chips 2, one after another for example, are detached from the wafer assembly 1 by a mechanical force F (FIG. 7).

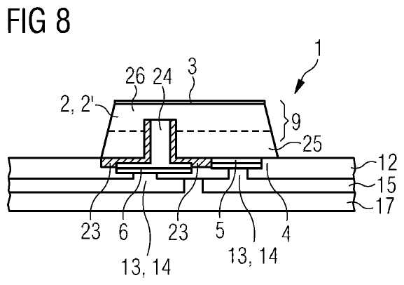

In contrast to the wafer assemblies 1 described so far, the wafer assembly 1 according to the exemplary embodiment of FIG. 8 comprises a plurality of flip-chips 2′. FIG. 8 here, for reasons of clarity, shows only one semiconductor chip 2.

The semiconductor chip 2 of the wafer assembly 1 according to the exemplary embodiment of FIG. 8 comprises an epitaxial semiconductor layer sequence 9 having an active zone 10 which in operation generates electromagnetic radiation.

The semiconductor chip 2 has a first main face 3 and a second main face 4 which is opposite the first main face 3. Disposed on the second main face 4 are a first electrical contact 5 and a second electrical contact 6, which are provided for the electrical contacting of the semiconductor chip 2. The first main face 3, however, is free of electrical contacts.

The first electrical contact 5 and the second electrical contact 6 are electrically insulated from one another by an electrically insulating layer 23. The electrically insulating layer 23 also extends over side faces of a via 24 and insulates the via 24 from the epitaxial semiconductor layer sequence 9.

The active zone 10 is disposed between a region 25 of a first conductivity type of the epitaxial semiconductor layer sequence 9 and a region 26 of a second conductivity type of the epitaxial semiconductor layer sequence 9. The region 25 of the first conductivity type is electrically contacted by the first electrical contact 5, while the region 26 of the second conductivity type is electrically contacted by way of the via 24 and of the second electrical contact 6.

The wafer assembly 1 additionally comprises an electrically insulating sacrificial layer 12 in which passages 13 are disposed. Disposed in the passages 13 are electrically conducting posts 14. The first electrical contact 5 is in direct contact with exactly one electrically conducting post 14 and in this way is connected to the electrically conducting post 14 in an electrically conducting manner. The second electrical contact 6 is in direct contact with exactly one further electrically conducting post 14 and in this way is connected to this electrically conducting post 14 in an electrically conducting manner. Alternatively, it is also possible for each first electrical contact and each second electrical contact to be assigned more than one electrically conducting post.

The description of the invention with reference to the exemplary embodiments does not confine the invention to these embodiments. Instead, the invention embraces every new feature and also every combination of features, including in particular every combination of features in the claims, even if that feature or that combination is not itself explicitly indicated in the claims or exemplary embodiments.

1-16. (canceled)

17. A wafer assembly comprising:
a plurality of semiconductor chips, wherein each semiconductor chip has a first main face and a second main face opposite the first main face, and wherein a first electrical contact is disposed on the second main face;
a plurality of electrically conducting posts, wherein each first electrical contact is in direct contact with an electrically conducting post;
an electrically insulating sacrificial layer having passages in which the electrically conducting posts are disposed; and
a predetermined breakage layer forming at least one end face of the electrically conducting post, wherein the predetermined breakage layer is directly adjacent to the first electrical contact.

18. The wafer assembly of claim 17, wherein the electrically insulating sacrificial layer extends over a full area along a back-side main face of the wafer assembly and embeds the first electrical contacts.

19. The wafer assembly of claim 17, wherein the semiconductor chip is free of a material which the electrically insulating sacrificial layer comprises.

20. The wafer assembly of claim 17, wherein an electrically conducting material of the electrically conducting post extends as an electrically conducting layer over a full area along a back-side main face of the wafer assembly.

21. The wafer assembly of claim 17, wherein a region of the electrically conducting post and a region of the first electrical contact which directly border one another comprise materials different from one another.

22. The wafer assembly of claim 21, wherein the electrically conducting material of the electrically conducting post is at least one of a TCO, a metal or a semimetal.

23. The wafer assembly of claim 17, wherein the first electrical contact comprises a first contact layer which is directly adjacent to the electrically conducting post.

24. The wafer assembly of claim 17, wherein the predetermined breakage layer extends over a full area along a back-side main face of the wafer assembly.

25. The wafer assembly of claim 17, wherein the predetermined breakage layer comprises a material different from a material of a region of the first electrical contact that is directly adjacent to the predetermined breakage layer.

26. The wafer assembly of claim 17, wherein a material of the predetermined breakage layer is different from a rest of a material of the electrically conducting post.

27. The wafer assembly of claim 17, wherein an edge length of the semiconductor chip is not greater than 100 micrometers.

28. A method for producing the plurality of semiconductor chips, the method comprising:
providing the wafer assembly according to claim 17; and
testing the semiconductor chips of the wafer assembly, the semiconductor chips being electrically contacted by way of a back-side main face of the wafer assembly.

29. The method of claim 28, further comprising removing the electrically insulating sacrificial layer from the wafer assembly.

30. The method of claim 28, further comprising mechanically parting the semiconductor chips from the electrically conducting posts.
